(19) United States
(12) Patent Application Publication
(10) Pub. No.: US 2017/0285706 A1
(43) Pub. Date: Oct. 5, 2017

(54) MULTI-LAYER STICKER CONTAINING A FLAT ELECTRONIC CIRCUIT

(71) Applicant: Power Me Tech Ltd., Bnei-Brak (IL)

(72) Inventors: Elena LITSYN, Tel-Aviv (IL); Ronen BARTAL, Hefer Valley Regional Council (IL)

(21) Appl. No.: 15/509,593

(22) PCT Filed: Sep. 9, 2015
(86) PCT No.: PCT/IL15/50918

§ 371 Date: Mar. 8, 2017

Related U.S. Application Data
(60) Provisional application No. 62/047,660, filed on Sep. 9, 2014.

(51) Int. Cl. G06F 1/26; G06F 1/16; H05K 3/00; H04W 52/02; H01R 24/60; H02J 7/00; H01M 10/42; H01M 10/44; H05K 1/18; H05K 1/02

(52) U.S. Cl. CPC G06F 1/266; H05K 1/189; G06F 1/1635; H05K 3/0058; H05K 1/028; G06F 1/1684; H01R 24/60; H02J 7/007; H01M 10/425; H01M 10/44; H04W 52/0296; H04W 52/0229; H05K 2201/10037; H05K 2201/10159; H01R 2107/00

(57) ABSTRACT

A multi-layer sticker is provided herein. The multi-layer sticker may include: a first attachment layer; an electronic circuitry layer comprising an electronic circuit suitable for connecting to a consumer electronics device, wherein the electronic circuitry layer is attached on one side to the first attachment layer; a second attachment layer coupled to first attachment layer; and an interface electrically coupled to the electronic circuit and configured to establish an electronic connection with the consumer electronics device.

### FIELD OF THE INVENTION

The present invention relates generally to the flat electronic circuits, and more specifically, to embedding flat electronic circuits into multi-layer stickers.

### BACKGROUND OF THE INVENTION

Prior to the background of the invention being set forth, it may be helpful to provide definitions of certain terms that will be used hereinafter.

The term ‘flexible electronics’ as used herein is defined as a technology for assembling electronic circuits by mounting electronic devices on flexible plastic substrates such as polyimide, Polyether ether ketone (PEEK) or transparent conductive polyester film. Flexible electronic assemblies may be manufactured using identical components used for rigid printed circuit boards, allowing the board to conform to a desired shape, or to flex during its use. These flexible printed circuits (FPC) are made with a photolithographic technology.

The term ‘attachment layer’ as used herein is defined as any surface-shaped layer which is made of a substrate that can typically attach two other surfaces together. The attachment of the surfaces may be in various manners such as: adhesive attachment, magnetic attachment, physical fastening, vacuum attachment, and chemical attachment

Power hungry devices such as smart telephones and tablet personal computers (Pcs) are in a never-ending shortage of power, frequently occurring when power is mostly needed. Similarly, other electronic circuits such as non-volatile memories are often required in order to deliver a large file to a consumer electronic device, when internet connectivity is limited or non-existent.

### SUMMARY OF THE INVENTION

Some embodiments of the present invention provide a multi-layer sticker having a flexible electronic circuit embedded within it. The multi-layer sticker may include: a first attachment layer; a flexible electronic circuitry layer comprising an electronic circuit suitable for connecting to a consumer electronics device, wherein the electronic circuitry layer is attached on one side to the first attachment layer; a second attachment layer coupled to first attachment layer; and an interface electrically coupled to the electronic circuit and configured to establish an electronic connection with the consumer electronics device.

These additional, and/or other aspects and/or advantages of the embodiments of the present invention are set forth in the detailed description which follows; possibly inferable from the detailed description; and/or learnable by practice of the embodiments of the present invention.

### BRIEF DESCRIPTION OF THE DRAWINGS

For a better understanding of embodiments of the invention and to show how the same may be carried into effect, reference will now be made, purely by way of example, to the accompanying drawings in which like numerals designate corresponding elements or sections throughout.

FIG. 1 illustrates the multi-layer sticker according to some embodiments of the present invention;

FIGS. 2A-2D illustrate the multi-layer sticker attached to various types of consumer products according to some embodiments of the present invention;

FIGS. 3A and 3B illustrate the multi-layer sticker attached to a consumer electronic device in accordance with another embodiment of the present invention;

FIG. 4 illustrates one aspect of the multi-layer sticker according to some embodiments of the present invention;

FIG. 5 illustrates another aspect of the multi-layer sticker according to some embodiments of the present invention;

FIGS. 6A and 6B illustrate various topologies of the multi-layer sticker according to some embodiments of the present invention;

FIGS. 7A and 7B are block diagrams illustrating various architectures of the multi-layer sticker according to some embodiments of the present invention;

FIGS. 8B and 8C illustrate existing embodiments that use mechanical switches that turn off the battery when the connector is not in use;

FIGS. 9A and 9B are block diagrams illustrating various architectures of the multi-layer sticker according to embodiments of the present invention; and

FIG. 10 is a graph diagram illustrating another aspect of some embodiments of the present invention.

### DETAILED DESCRIPTION OF THE INVENTION

With specific reference now to the drawings in detail, it is stressed that the particulars shown are by way of example and for purposes of illustrative discussion of the preferred embodiments of the present technique only, and are presented in the cause of providing what is believed to be the most useful and readily understood description of the principles and conceptual aspects of the present technique. In this regard, no attempt is made to show structural details of the present technique in more detail than is necessary for a fundamental understanding of the present technique, the description taken with the drawings making apparent to those skilled in the art how the several forms of the invention may be embodied in practice.

Before at least one embodiment of the present technique is explained detail, it is to be understood that the invention is not limited in its application to the details of construction and the arrangement of the components set forth in the following description or illustrated in the drawings. The present technique is applicable to other embodiments or of being practiced or carried out in various ways. Also, it is to be understood that the phraseology and terminology employed herein is for the purpose of description and should not be regarded as limiting.

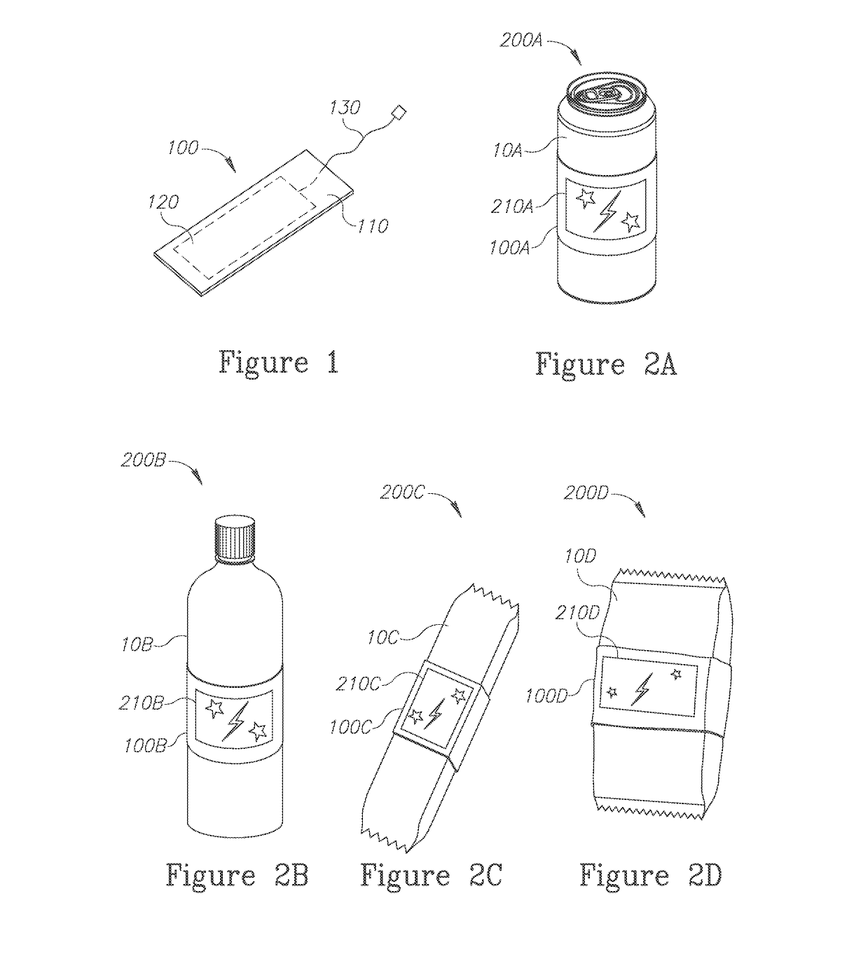

FIG. 1 illustrates a multi-layer sticker 100 according to sonic embodiments of the present invention. Multi-layer sticker 100 may include a multi-layer structure 110 having a flat electronic circuit 120 embedded within it. The overall thickness of multi-layer sticker 100 may he of a few millimeters so that multi-layer sticker 100 maintains its flexibility as a sticker. Electronic circuit 120 may be connected to an interface wire 130 such as a universal serial bus (USB) line. Interface 130 is connectable to any computer electronics device which complies with the power/communication standard of the interface 130.

According to some embodiments of the present invention, the multi-layer sticker may include a first attachment layer; an electronic circuitry layer comprising an electronic circuit suitable for connecting to a consumer electronics device, wherein the electronic circuitry layer is attached on one side to the first attachment layer; a second attachment layer coupled to first attachment layer; and an interface electrically coupled to the electronic circuit and configured to establish an electronic connection with the consumer electronics device.

According to some embodiments of the present invention, the first attachment layer and the second attachment layer are attached to each other. The second attachment layer may he coupled to the first attachment layer via the electronic circuitry layer.

According to some embodiments of the present invention, the first attachment layer and the second attachment layer are coupled to each other via a detachment layer facilitating the detachment of the first attachment layer from the second attachment layer upon pulling the detachment layer.

According to some embodiments of the present invention, wherein at least one of the attachment layers comprises an adhesive substance.

According to some embodiments of the present invention, at least one of the attachment layers comprises a magnetic substance.

According to some embodiments of the present invention, the interface comprises a universal serial bus (USB) interface.

According to some embodiments of the present invention, the USB interface complies with USB on-the-go standard.

The multi-layer sticker according to claim 1, wherein the electronic circuit is a primary power source suitable for powering the consumer electronics device. FIGS. 2A-2D depict non-limiting examples illustrating several multi-layer stickers 100A-100D attached to different types of consumer products such as beverage can 200A, bottle 200B, chocolate bar 200C, and a snack 200D, according to some embodiments of the present invention.

As explained above, multi-layer stickers 100A-100D may be produced sufficiently thin so as to preserve it flexibility and so multi-layer stickers 100A-100D may be easily attached to outer surfaces 10A-10D of consumer products 200A-200D, respectively. In accordance with some embodiments, visual contents 210A-210D may be printed or otherwise provided onto at least one of the surface of consumer products 200A-200D. Visual contents 210A-210D may be in a form of an advertisement or otherwise related contextually to consumer products 200A-200D.

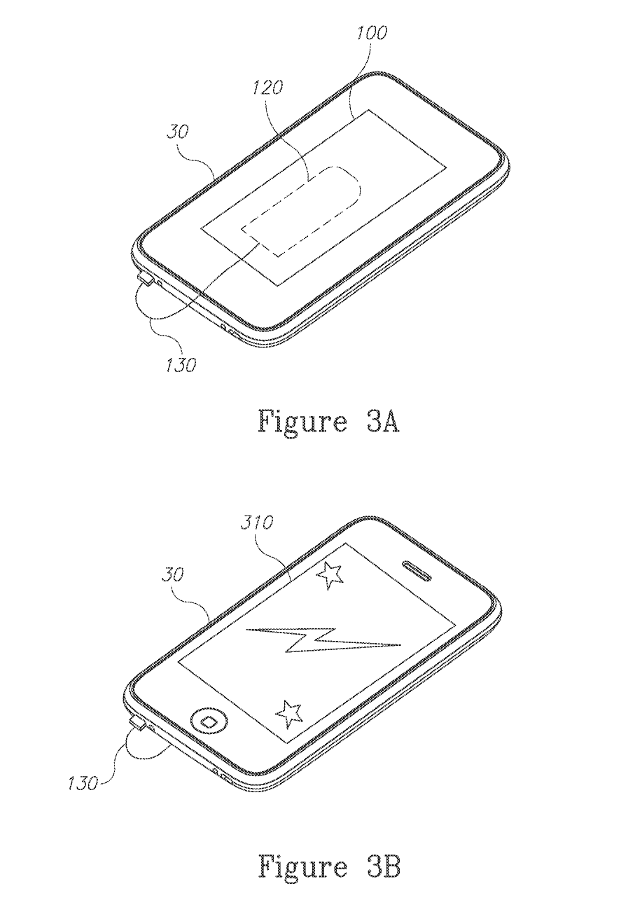

FIGS. 3A and 3B illustrate the multi-layer sticker 100 attached to a consumer electronics device 30 (e.g., a smart telephone) in accordance with another embodiment of the present invention. FIG. 3A shows how multi-layer sticker 100 having electronic circuit 120 within it, is being attached to one surface of consumer electronics device with interface 130 (e.g. USB wire) electronically connecting multi-layer sticker 100 to a consumer electronics device 30. FIG. 39 shows the other surface of consumer electronics device 30 (e.g. a display) with multi-layer sticker 100 attached to its back side. In some embodiment, electronically connecting multi-layer sticker 100 to consumer electronics device 30 result in at least temporal appearance of some predefined visual content 310 over the display of consumer electronics device 30.

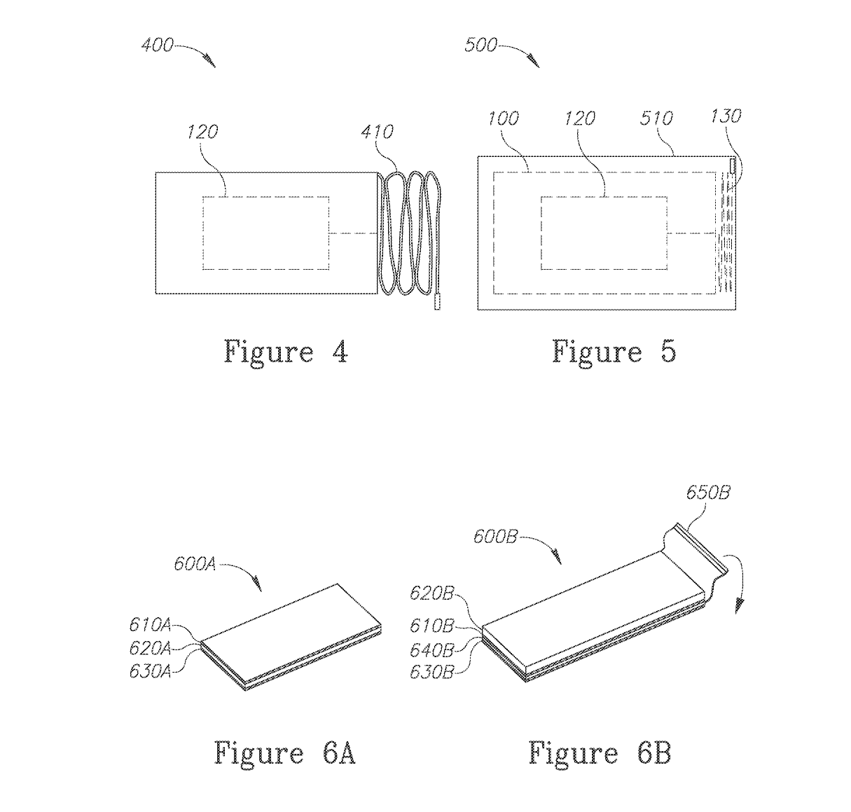

FIG. 4 illustrates one aspect of the multi-layer sticker according to some embodiments of the present invention. Multi-layer sticker 400 is illustrated with electronic circuit 120 embedded within it and the interface 410 is shown to be cut of or formed of the same material as at least one of the layers of multi-layer sticker 400. Advantageously this may result in a reduction of the overall manufacturing costs.

FIG. 5 illustrates another aspect of the multi-layer sticker according to some embodiments of the present invention. Multi-layer sticker 500 is illustrated with electronic circuit 120 embedded within it and entire multi-layer structure 100 including the interface 130 (e.g. USB line) is shown to he packed in a package 510 (e.g. film package).

FIGS. 6A and 6B illustrate various topologies of the multi-layer sticker according to some embodiments of the present invention. FIG. 6A shows multi-layer sticker 600A including an upper first attachment layer 610A, a lower second attachment layer 630A and in between them, flexible electronics layer 620. Each of attachment layers may be used to attach flexible electronics layer 620 (e.g. adhesively) to a third surface. FIG. 6B shows an alternative topology of multi-layer sticker 600B including an upper electronic layer 620B, a middle first attachment layer 610B, a lower second attachment layer 630B and in between them, a detachment film 640B having a portion 650B extending beyond the layers of the multi-layer sticker. In this configuration, multi-layer sticker may be attached initially to a first surface via lower attachment layer 630B. Then using extending portion 650B middle attachment layer may be exposed, having lower attachment layer 630B removed, so that multi-layer sticker 600B may be attached to a different surface via middle first attachment layer 610B.

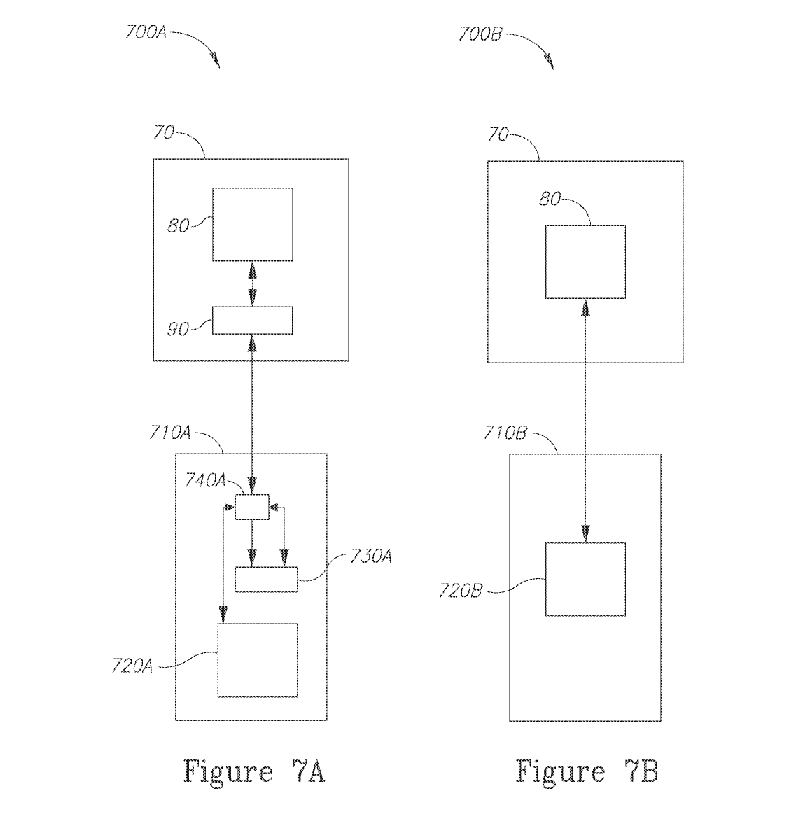

FIGS. 7A and 7B are block diagrams illustrating various architectures of the multi-layer sticker according to some embodiments of the present invention. FIG. 7A illustrates a consumer electronics device 70 having a processor 80 and a power management unit 90. Electronic layer 710A of multi-layer sticker may include a primary power source 720A a non-volatile memory 730A and logic 740A configured to manage connection established between multi-layer sticker and consumer electronics device 70. In operation, logic 740A may interact with consumer electronics device 70 and allow direct powering of consumer electronics device 70 by power source 720A. Alternatively, logic 740A may assume control over power management unit of consumer electronics device 70. Additionally, non-volatile memory 730A may be used hi-directionally for both uploading data to consumer electronics device 70 and downloading data from consumer electronics device 70. FIG. 7A shows a more simplified architecture with a single circuit (e.g. power source, non-volatile memory)on the multi-layer sticker.

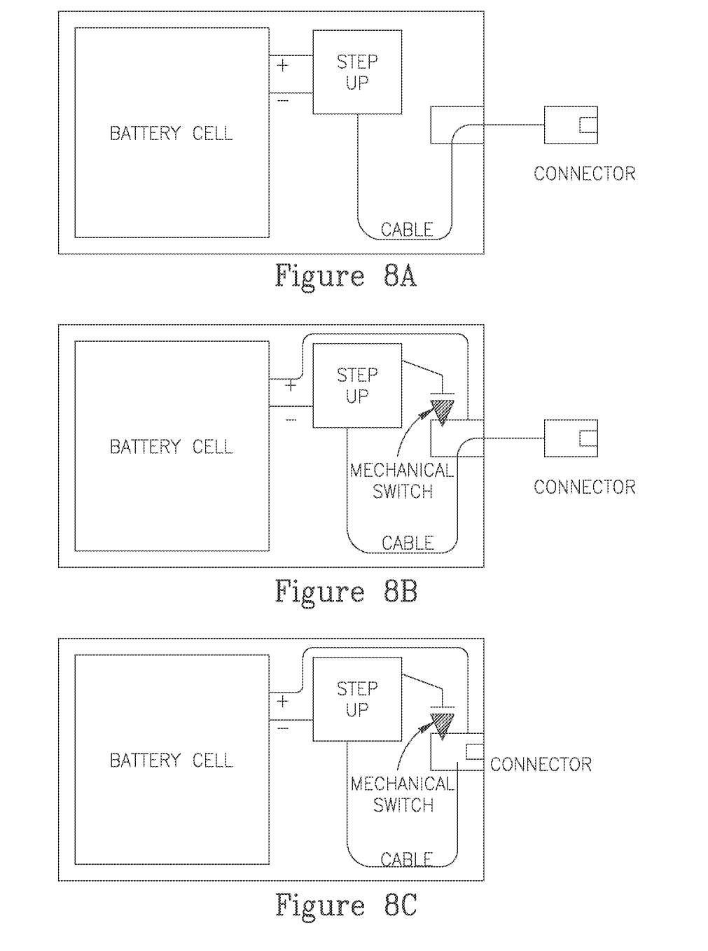

FIGS. 8A-8C are block diagrams illustrating various architectures of the multi-layer sticker according to the prior art. USB charging scheme requires voltage of 5V, in some cases devices will charge in less than 4V as well. When using a battery cell of 3V and less there is a need for step up (boost). This is electronic circuitry that converts a DC of 3V (or less) to higher DC voltage (in that case 5V). This electronic circuitry has a leakage current which discharge the battery cell even if the output is not connected.

It is may be advantageous to be able reduce the aforementioned leakage current minimum when no load is connected. FIGS. 8B and 8C illustrate existing embodiments that use mechanical switches that turn off the battery when the connector is not in use. Such a mechanical switch requires moving parts chick complicate the structure and also increase the cost of production.

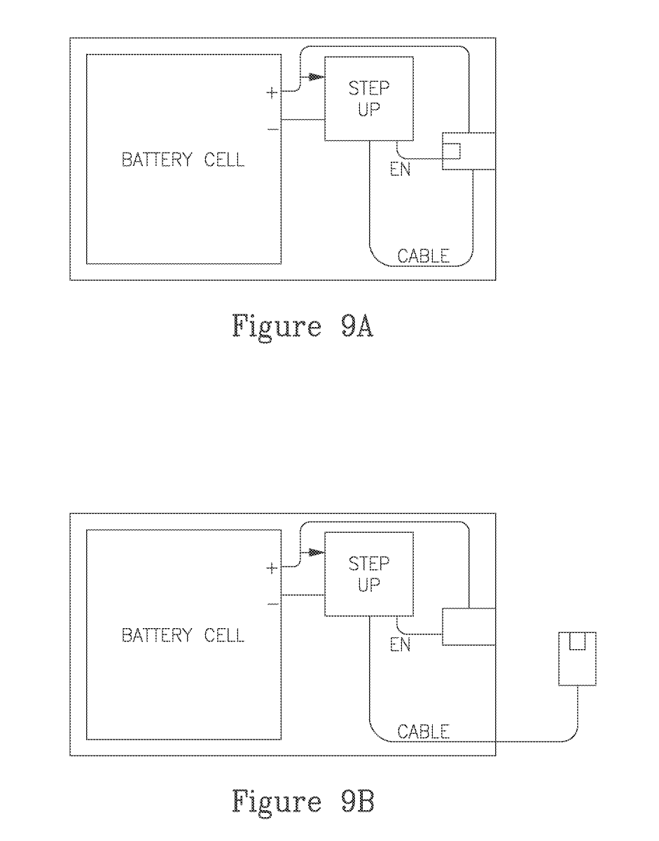

FIGS. 9A and 9B are block diagrams illustrating various architectures of the multi-layer sticker which provide a more elegant solution to reducing the leakage current, according to embodiments of the present invention. In order to overcome the problem of leakage current and at the same time not increase the cost of the switching mechanism such as with the aforementioned mechanical switch, embodiments of the present invention use an existing internal connection of the USB connector (internal short between D+ and D−) to detect whether the connector is not in used by the loading device (smartphone). Specifically, the internal shortcut is configured to receive power from the battery and route it to the enable pin of the DC-DC converter. Thus, as long as the connector is located within the package, it guarantees that the DC-DC converter is disabled.

It is understood that D+ and D− are just one embodiment and the aforementioned mechanism of electronic switch can work on other pins using a pull up or pull down resistor. Specifically, any mechanism that disables the DC-DC converter as long as the electrical cable/USB plug can be used herein.

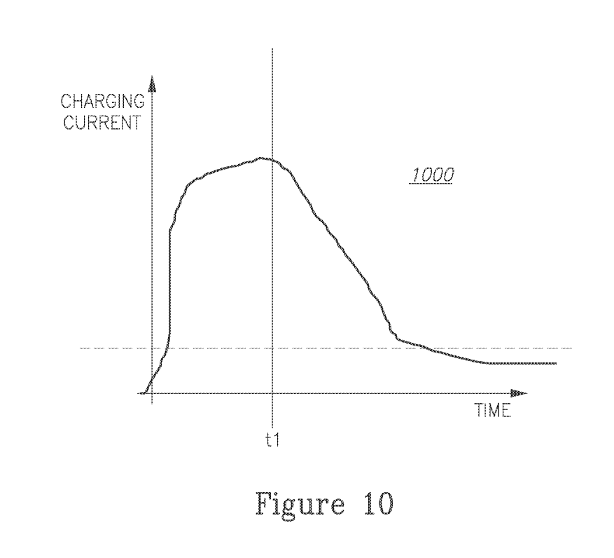

FIG. 10 is a graph diagram illustrating another aspect of some embodiments of the present invention. According to an additional embodiment of the preset invention it is suggested to change the charging profile of the consumer electronic device connected to the battery, in order to optimize the use of electrical charge. The suggested profile is given in graph 1000 in which charging current (delivered from battery to consumer electronic device) is shown versus time.

More specifically, when using a disposable battery to charge a consumer electronic device, such as a smartphone, there are two contradicting requirements:
1. The need to charge the device as quick as possible—this require high current charging
2. The need to optimize the battery capacity.

Each battery has an internal resistance, the higher the internal resistance the lower the battery efficiency as a lot of the energy is dissipated on the internal resistance. In Lithium cells the internal resistance is affecting discharge current. The higher the discharge current, the lower the battery efficiency. Therefore, in order to maximize the battery efficiency there is a need to discharge the battery at a low current

In order to cope with these two contradicting requirement, the inventors have developed a mechanism that draws from the battery high current when the device (phone) battery is very low and after the device wakes up (at time=t₁ shown in graph 1000). According to embodiments of the present invention the internal circuitry of the battery senses the wake up and reduces the charging current in order to maximize the battery efficiency. Using this mechanism can improve battery effective capacity by 20-30% depends on the load.

According to some embodiments of the present invention, the interface within the flat battery sticker is configured to apply a high charging current to the battery of the consumer electronic product, whenever the battery of the consumer electronic product is below a specific threshold and significantly reduce the charging current once the charge level at the battery of the consumer electronic product is above the specific threshold. Then the interface will switch to the lower level of current once a “wake-up” of the charged consumer electronic product is detected.

According to some embodiments of the present invention, the battery will include a memory unit and a logic unit, wherein the memory unit is configured to store a executable code and wherein the logic unit is configured to load the executable code onto the consumer electronics device via the interface upon coupling the consumer electronics device to the interface.

According to some embodiments of the present invention, the executable code is configured, when executed by a processor of the consumer electronics device, to manage the power consumption of the consumer electronics device.

According to some embodiments of the present invention, the managing the power consumption of the consumer electronics device reducing a number of processes running over the processor.

According to some embodiments of the present invention, the executable code is configured, when executed by a processor of the consumer electronics device, to present predefined content over a display of the consumer electronics device.

According to some embodiments of the present invention, the electronic circuit comprises a memory unit and a logic unit, wherein the memory unit is configured to store a content and wherein the logic unit is configured to load the content onto the consumer electronics device via the interface upon coupling the consumer electronics device to the interface.

According to some embodiments of the present invention, the memory unit comprises non-volatile memory configured as an external storage unit to the consumer electronics device.

According to some embodiments of the present invention, at least one of the films exhibits visual content.

According to some embodiments of the present invention, the content comprises an advertisement.

According to some embodiments of the present invention, the multi-layer sticker may include a wrap configured to house electronic circuitry layer.

According to some embodiments of the present invention, the primary power source is configured to store electrical energy sufficient for powering the consumer electronics device for at least 5 minutes, independently of a power source of the consumer electronics device.

According to some embodiments of the present invention, the consumer electronics device comprises at least one of: a smart telephone, a cellular communication device, a tablet personal computer (PC); and a lap top PC.

According to some embodiments of the present invention, at least some of the interface is formed by the electronic circuitry layer.

According to some embodiments of the present invention, the first attachment layer is suitable for attaching to a product and wherein the second attachment layer is suitable for attaching to the consumer electronics device.

In the above description, an embodiment is an example or implementation of the inventions. The various appearances of “one embodiment,” “an embodiment” or “some embodiments” do not necessarily all refer to the same embodiments.

Although various features of the invention may be described in the context of a single embodiment, the features may also be provided separately or in any suitable combination. Conversely, although the invention may be described herein in the context of separate embodiments for clarity, the invention may also be implemented in a single embodiment.

Reference in the specification to “some embodiments”, “an embodiment”, “one embodiment” or “other embodiments” means that a particular feature, structure, or characteristic described in connection with the embodiments is included in at least some embodiments, but not necessarily all embodiments, of the inventions.

It is to be understood that the phraseology and terminology employed herein is not to be construed as limiting and are for descriptive purpose only.

The principles and uses of the teachings of the present invention may be better understood with reference to the accompanying description, figures and examples. It is to be understood that the details set forth herein do not construe a limitation to an application of the invention.

Furthermore, it is to be understood that the invention can be carried out or practiced in various ways and that the invention can be implemented in embodiments other than the ones outlined in the description above.

It is to be understood that the terms “including”, “comprising”, “consisting” and grammatical variants thereof do not preclude the addition of one or more components, features, steps, or integers or groups thereof and that the terms are to be construed as specifying components, features, steps or integers.

If the specification or claims refer to “an additional” element, that does not preclude there being more than one of the additional element.

It is to be understood that where the claims or specification refer to “a” or “an” element, such reference is not be construed that there is only one of that element.

It is to be understood that where the specification states that a component, feature, structure, or characteristic “may”, “might”, “can” or “could” be included, that particular component, feature, structure, or characteristic is not required to be included.

Where applicable, although state diagrams, flow diagrams or both may be used to describe embodiments, the invention is not limited to those diagrams or to the corresponding descriptions. For example, flow need not move through each illustrated box or state, or in exactly the same order as illustrated and described.

Methods of the present invention may be implemented by performing or completing manually, automatically, or a combination thereof, selected steps or tasks.

The descriptions, examples, methods and materials presented in the claims and the specification are not to be construed as limiting but rather as illustrative only.

Meanings of technical and scientific terms used herein are to be commonly understood as by one of ordinary skill in the art to which the invention belongs, unless otherwise defined.

The present invention may be implemented in the testing or practice with methods and materials equivalent or similar to those described herein.

While the invention has been described with respect to a limited number of embodiments, these should not be construed as limitations on the scope of the invention, but rather as exemplifications of some of the preferred embodiments. Other possible variations, modifications, and applications are also within the scope of the invention. Accordingly, the scope of the invention should not be limited by what has thus far been described, but by the appended claims and their legal equivalents.

1. A multi-layer sticker comprising:
a first attachment layer;
an electronic circuitry layer comprising an electronic circuit suitable for connecting to a consumer electronics device, wherein said electronic circuitry layer is attached on one side to said first attachment layer;
a second attachment layer coupled to said first attachment layer; and
an interface electrically coupled to said electronic circuit and configured to establish an electronic connection with said consumer electronics device
wherein said electronic circuit comprises a primary power source suitable for powering said consumer electronics device, said primary power source is configured to store electrical energy sufficient for powering said consumer electronics device for at least 5 minutes, independently of a power source of said consumer electronics device.

2. The multi-layer sticker according to claim 1, wherein each of said first attachment layer and said second attachment layer is individually covered by a protective film.

3. The multi-layer sticker according to claim 1, wherein said first attachment layer and said second attachment layer are attached to each other.

4. The multi-layer sticker according to claim 1, wherein said second attachment layer is coupled to said first attachment layer via said electronic circuitry layer.

5. The multi-layer sticker according to claim 1, wherein said first attachment layer and said second attachment layer are coupled to each other via a detachment layer facilitating the detachment of said first attachment layer from said second attachment layer upon pulling said detachment layer.

6. The multi-layer sticker according to claim 1, wherein at least one of said first attachment layer and/or said second attachment layer comprises an adhesive substance and/or a magnetic substance.

7. (canceled)

8. The multi-layer sticker according to claim 1, wherein said interface comprises a universal serial bus (USB) interface.

9-10. (canceled)

11. The multi-layer sticker according to claim 10, further comprising a memory unit and a logic unit, wherein said memory unit is configured to store an executable code and wherein said logic unit is configured to load said executable code onto said consumer electronics device via said interface upon coupling said consumer electronics device to said interface.

12. The multi-layer sticker according to claim 11, wherein said executable code is configured, when executed by a processor of said consumer electronics device, to manage a power consumption of said consumer electronics device.

13. The multi-layer sticker according to claim 12, wherein managing said power consumption of said consumer electronics device comprises reducing a number of processes running on said processor.

14. The multi-layer sticker according to claim 11, wherein said executable code is configured, when executed by a processor of said consumer electronics device, to present predefined content over a display of said consumer electronics device.

15. The multi-layer sticker according to claim 1, wherein said electronic circuit comprises a memory unit and a logic unit, said memory unit is configured to store a content and said logic unit is configured to load said content onto said consumer electronics device via said interface upon coupling said consumer electronics device to said interface.

16. The multi-layer sticker according to claim 15, wherein said memory unit comprises non-volatile memory configured as an external storage unit to said consumer electronics device.

17. The multi-layer sticker according to claim 42, wherein said film comprises a visually readable content.

18-20. (canceled)

21. The multi-layer sticker according to claim 1, wherein said consumer electronics device is selected from the group consisting of a smart telephone, a cellular communication device, a tablet personal computer (PC) and a lap top computer.

22. The multi-layer sticker according to claim 1, wherein said interface is formed at least partially by said electronic circuitry layer.

23. The multi-layer sticker according to claim 1, wherein said first attachment layer is suitable for attaching to a product and wherein said second attachment layer is suitable for attaching to said consumer electronics device.

24. The multi-layer sticker according to claim 10, wherein said interface comprises a DC-DC converter and power interface having an internal shortcut between two pins, and wherein said shortcut is configured, in non-operational state of said primary power source to route a wire coming from said primary power source into an enable pin of the DC-DC converter thereby disabling the DC-DC converter as long as the power interface is positioned within the packaging of the multi-layer sticker.

25. The multi-layer sticker according to claim 10, wherein, said interface is configured to apply a charging current at a high level to a battery of said consumer electronic product, when said battery is below a specific threshold, and further configured to apply said charging current at a lower level once a charge level at said battery is above said specific threshold.

26. The multi-layer sticker according to claim 25, wherein said interface switches to said lower level once a “wake-up” of said charged consumer electronic product is detected.
